(19) United States
(12) Patent Application Publication
(10) Pub. No.: US 2017/0270442 A1
(43) Pub. Date: Sep. 21, 2017

(54) INFRASTRUCTURE WORKING BEHAVIOUR CHARACTERISATION

(71) Applicant: National ICT Australia Limited, Eveleigh, NSW (AU)

(72) Inventors: Matt Zhang, Eveleigh, NSW (AU); Yang Wang, Eveleigh, NSW (AU); Fang Chen, Eveleigh, NSW (AU)

(21) Appl. No.: 15/532,030

(22) PCT Filed: Dec. 9, 2015
(86) PCT No.: PCT/AU2015/050776

§ 371 Date: May 31, 2017

(30) Foreign Application Priority Data
Dec. 9, 2014 (AU) 2014904970
Feb. 6, 2015 (AU) 2015900384

(51) Int. Cl. G06Q 10/06; G01R 31/40; G06Q 10/04; G06Q 50/06; G06N 7/00

(52) U.S. Cl. CPC G06Q 10/0635; G06Q 50/06; G06N 7/005; G06Q 10/04; G01R 31/40

(57) ABSTRACT

The present disclosure generally relates to infrastructure health condition estimation. There is provided a computer-implemented method for characterising behaviours of working events of components of an infrastructure (110), the working events comprising previous working events. The method comprises obtaining historical data representing the previous working events of the components (112) of the infrastructure (110); and determining, based on the historical data, values of parameters of a stochastic process model to characterise the behaviours of the working events, wherein the stochastic process model comprises a set of Hawkes processes that characterise occurrences of the working events and a Bayesian nonparametric process that characterises dependency of the working events.

### CROSS-REFERENCE TO RELATED APPLICATIONS

The present application claims priority from the Australian provisional application 2014904970 filed on 9 Dec. 2014, and the Australian provisional application 2015900384, filed on 6 Feb. 2014, with National ICT Australia being the applicant and the contents of which are incorporated herein by reference.

### TECHNICAL FIELD

The present disclosure generally relates to infrastructure health condition estimation. The present disclosure includes computer-implemented methods, software, and computer systems for characterising behaviours of working events of components of an infrastructure.

### BACKGROUND

Infrastructures play an important role in the operation of society. Infrastructures provide necessary public or private services including water supply, electric power supply, transport services, communication services, etc. Depending on the type of the service an infrastructure provides, the infrastructure may include a water supply network, a power supply network, a road and bridge network, and a telecommunication or television network. The term “infrastructure” used in the present disclosure may also include service networks of other forms, for example, a financial network. On the other hand, the infrastructure in the present disclosure may not be limited to a network for use in the operation of society, the infrastructure may also include a circuit network on a semiconductor chip that performs certain functions. Even broader, the infrastructure in the present disclosure may include a geologic system, a social system or an ecological system.

An infrastructure includes a plurality of components. For example, a water supply network may include thousands or millions of water pipes. The components in the present disclosure may be referred to as assets. The health condition of the components of infrastructure may change over time due to material degradation, environmental changes, or may be damaged by human activities. Therefore, the health condition of an infrastructure needs to be monitored and managed in a proper way.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

Any discussion of documents, acts, materials, devices, articles or the like which has been included in the present disclosure is not to be taken as an admission that any or all of these matters form part of the prior art base or were common general knowledge in the field relevant to the present disclosure as it existed before the priority date of each claim of this application.

### SUMMARY

There is provided a computer-implemented method for characterising behaviours of working events of components of an infrastructure, the working events comprising previous working events, the method comprising:
obtaining historical data representing the previous working events of the components of the infrastructure; and
determining, based on the historical data, values of parameters of a stochastic process model to characterise the behaviours of the working events, wherein the stochastic process model comprises a set of Hawkes processes that characterise occurrences of the working events and a Bayesian nonparametric process that characterises dependency of the working events.

It is an advantage of the present disclosure that the dependency of the working events that occur in accordance with the set of Hawkes processes is characterised by the Bayesian nonparametric process. The dependency of the working events serves as prior knowledge on occurrences of the working events, which enhances the set of Hawkes processes. As a result, the behaviours of the working events may be accurately characterised by the stochastic process model, and an accurate estimate of a quantity of future working events may be achieved based on one of the set of Hawkes processes.

Determining the values of the parameters of the stochastic process model may comprise determining values of parameters of the set of Hawkes processes and values of variables of the Bayesian nonparametric process.

The Bayesian nonparametric process may comprise a spatiotemporal distance dependent Chinese restaurant process (stddCRP).

Determining the values of the variables of the Bayesian nonparametric process may comprise determining values of variables of the stddCRP, wherein each of the variables of the stddCRP is associated with a previous working event of the previous working events and the value of the variable associated with the previous working event indicates the dependency of the previous working event.

Determining the values of variables of the stddCRP may comprise updating the values of the variables of the stddCRP based on the values of the parameters of the set of Hawkes processes.

Updating the values of the variables of the stddCRP may comprise updating the values of the variables of the stddCRP based on values of attributes of the components.

Determining the values of the parameters of the set of Hawkes processes may comprise updating the values of the parameters of the set of Hawkes processes based on the dependency of the previous working events.

Updating the values of the parameters of the set of Hawkes processes may comprise updating the values of the parameters of the set of Hawkes processes based on the values of the attributes of the components.

The attributes of the components may comprise age, diameter, length, material and coating of the components.

Updating the values of the parameters of the set of Hawkes processes may further comprise:
determining types of the previous working events based on the dependency of the previous working events; and
updating the values of the parameters of the set of Hawkes processes based on the types of the previous working events.

Determining the types of the previous working events may comprise determining a first portion of the previous working events to be background events if the values of variables of the stddCRP associated with the first portion of the previous working events indicate that each working event of the first portion of the previous working events is dependent on itself.

Determining the types of the previous working events may comprise determining a second portion of the previous working events to be triggered events if the values of variables of the stddCRP associated with the second portion of the previous working events indicate that each working event of the second portion of the previous working events is dependent on another previous working event.

Updating the values of the parameters of the set of Hawkes processes may comprise updating the values of one or more of the parameters of the set of Hawkes processes based on the first portion of the previous working events that are determined to be background events.

Updating the values of the parameters of the set of Hawkes processes may comprise updating the values of one or more of the parameters of the set of Hawkes processes based on the second portion of the previous working events that are determined to be triggered events.

The dependency of the working events may comprise temporal dependency and spatial dependency.

The temporal dependency may comprise a first difference between times of the occurrences of a first previous working event and a second previous working event, and the spatial dependency may comprise a second difference between locations of the occurrences of the first previous working event and the second previous working event.

If the first difference is less than a first threshold and the second difference is less than a second threshold, the second previous working event is dependent on the first previous working event.

There is provided a computer-implemented method for estimating a quantity of future working events of a component of an infrastructure, comprising:
obtaining values of parameters of a Hawkes process determined according to one or more methods as described above where appropriate and values of attributes of the component; and
estimating the quantity of future working events of the component based on the Hawkes process and the values of the attributes of the component.

The working events may comprise failures of the components of the infrastructure.

Determining the quantity of working events of the component may comprise:
determining an expression for the Hawkes process based on the values of the parameters; and
integrating the expression for the Hawkes process over a period of time.

Integrating the expression for the Hawkes process may comprise:
determining part of the expression for the Hawkes process that characterises occurrences of background events of the working events; and
integrating the part of the expression over the period of time.

There is provided a computer software program, including machine-readable instructions, when executed by a processor, causes the processor to perform one or more methods as described above where appropriate.

There is provided a computer system for characterising behaviours of working events of components of an infrastructure, the working events comprising previous working events, the computer system comprising:
a communication port to obtain historical data representing the previous working events of the components of the infrastructure; and
a processor, comprising:
   a Hawkes process unit to determine, based on the historical data, values of parameters of a set of Hawkes processes, wherein the set of Hawkes processes characterise occurrences of the working events; and
   a dependency unit to determine, based on the historical data, values of variables of a Bayesian nonparametric process, wherein the Bayesian nonparametric process characterises dependency of the working events.

There is provided a computer system for estimating a quantity of future working events of a component of an infrastructure, comprising:
a communication port to obtain values of parameters of a Hawkes process determined according to one or more methods described above where appropriate, and values of attributes of the component; and
a processor, comprising
   an event estimation unit to estimate the quantity of future working events of the component based on the Hawkes process and the values of the attributes of the component.

The event estimation unit may further comprise:
determine an expression for the Hawkes process based on the values of the parameters; and
integrate the expression for the Hawkes process over a period of time.

### BRIEF DESCRIPTION OF THE DRAWINGS

Features of the present disclosure are illustrated by way of non-limiting examples, and like numerals indicate like elements, in which:

FIG. 1 illustrates an example system that includes an infrastructure in accordance with the present disclosure;

FIG. 2 illustrates an example method for characterising behaviours of working events of components of an infrastructure in accordance with the present disclosure;

FIG. 3 illustrates a further example method for characterising behaviours of working events of components of an infrastructure in accordance with the present disclosure;

FIG. 4 illustrates an example method for estimating a quantity of future working events of a component of an infrastructure in accordance with the present disclosure;

FIGS. 5(a) and 5(b) illustrate a performance analysis of the methods in accordance with the present disclosure;

FIG. 6 illustrates a further performance analysis of the methods in accordance with the present disclosure; and

FIG. 7 illustrates an example schematic diagram of a computing device in accordance with the present disclosure.

### BEST MODES OF THE DISCLOSURE

System Description

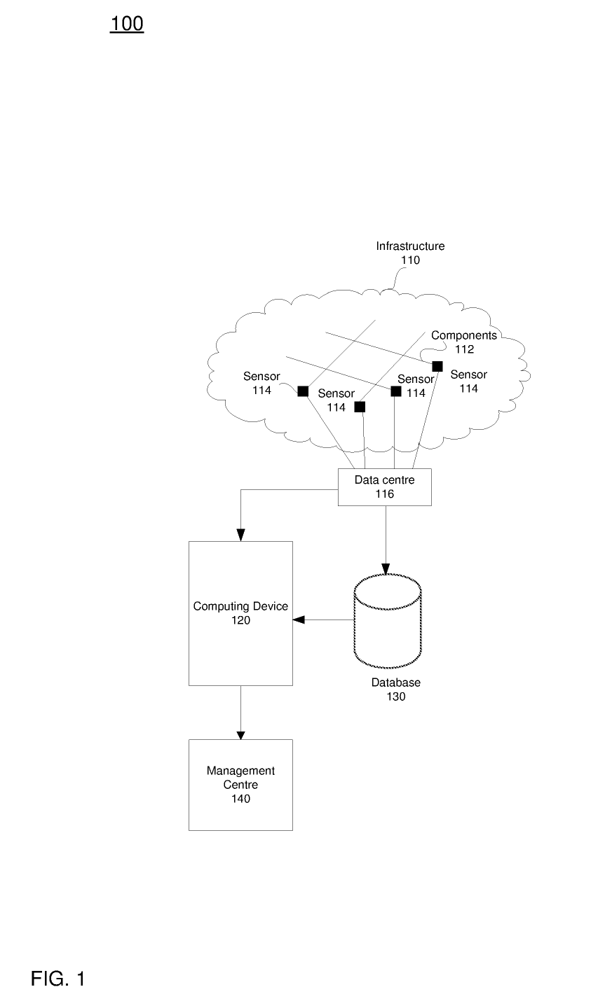

FIG. 1 illustrates an example system 100 that includes an infrastructure 110, which in turn includes a plurality of components 112.

In the example shown in FIG. 1, the infrastructure 110 is a water supply network. Accordingly, the components 112 of the infrastructure 110 include water pipes 112. It should be noted that, as described above, the infrastructure 110 may also be a power supply network, a road and bridge network, a telecommunication or television network, or a circuit network, or other networks that offer certain services or functions, or even a geologic system, a social system or an ecological system, without departing from the scope of the present disclosure.

The health conditions of the components 112 may be monitored by sensors 114 that are coupled to the components 112. For example, the sensor 114 may be a pressure sensor that detects the pressure in the water pipe 112. A over high or over low pressure in the water pipe 112 may indicate the water pipe 112 fails, while a pressure in an appropriate range may indicate the water pipe 112 is in normal health conditions. The sensor 114 may also be an ultrasound sensor that detects cracks on the water pipe 112. Similarly, detection of cracks on the water pipe 112 may indicate a failure of the water pipe 112. Even more directly, the sensors 114 may be able to detect actual health conditions.

Note that the term “health condition” used in the present disclosure indicates a working status of the component 112, which may be understood by a person skilled in the art to be a normal working status, a failure, or a working status that is between a normal working status and a failure. A working event occurs if the health condition meets certain criteria. For example, if the component 112 is fully working, the working event that is occurring to this component 112 is normal, if the component 112 is not working, the working event is failure. A working event may also be defined by a health condition of the component 112 that is in a range between normal working status and failure without departing from the scope of the present disclosure.

The sensors 114 may be coupled to the components 112 mechanically, electrically, electromagnetically or in other appropriate ways to monitor health conditions of the components 112.

Data that are collected by the sensors 114 are sent from the sensors 114 to a data centre 116. The data centre 116 may compile the data into a data record that is suitable for further process by a computing device 120 or storage in a database 130. For example, a sensor reading of no pressure in a water pipe for a certain period of time may be recorded in the data record as a working event, particularly, a failure. Alternatively, the water pressure of the pipe over a period of time could be made a further indicator, such as the average pressure, or number of times the pressure is higher or lower than a threshold. The compiled data are referred to as historical data in the present disclosure, which represent previous working events of the components 112 of the infrastructure 110. In other examples, the compiling of the data may be performed by the computing device 120 or the database 130 without departing from the scope of the present disclosure. In other examples, the historical data may not include data from the sensors 114. For example, the historical data may simply be pre-stored in the database 130 and the computing device 120 may simply obtain the historical data from the database 130.

Based on the historical data obtained from the data centre 116 or the database 130, the computing device 120 may perform analysis on the health conditions of the components 112. For example, the computing device 120 may estimate a working event rate or a working event probability for each component 112 in a future period of time. Particularly, if the working event is defined as a failure, the computing device 120 may estimate a failure rate or a failure probability for each component 112 in the next year.

The outcome of the analysis is sent by the computing device 120 to a computer system of a management centre 140. The outcome may be sent in an electronic message. The outcome in the electronic message may trigger the management centre 140 to execute certain management functions. For example, if the failure probability of a particular component 112 is higher than a threshold, the management centre 140 may automatically schedule a maintenance activity for the component 112 to prevent failure of the component 112 in the next year. Alternatively or in addition, additional data could be stored, such as to the database 130, to reflect the outcome of the analysis or displayed in a screen connected directly or indirectly to the computing device 120. As a result, the health condition of the infrastructure 110 may be improved.

It should be noted that although the data centre 116, the computing device 120, the database 130 and the management centre 140 are shown as separate entities in FIG. 1, one or more of these entities can be part of other entities without departing from the scope of the present disclosure. For example, the database 130 may be a logical or a physical part of the computing device 120.

Behaviours of Working Events

The working events occur for many reasons. Particularly, for the water supply network 110 shown in FIG. 1, the components 112 may fail for material fatigue, structural degradation and corrosion, etc.

The working events of the components 112 occur at a certain rate, which represents how many working events occur within a unit of time, for example per second, per minute, even per month or per year. The occurrence rate of the working events may be a constant or a function varying over time.

On the other hand, the behaviours of the working events exhibit spatiotemporal clustering feature, which means that a working event can trigger another one within a relatively close spatiotemporal distance via a certain manner of triggering. That is, a working event may depend on another working event. Take a geologic system as an example, the generation of aftershocks of an earthquake are generally triggered by main shocks via seismic waves.

Since a working event can be considered as spatiotemporal diffusible events, the working event may be categorized into two types: (1) a background event and (2) a triggered event, which in turn reflects dependence of the working event.

A background event is a working event that is not triggered by other working events, which may be caused by inherent factors of the components 112. For the above-mentioned geologic system, the main shocks may be considered as the background events, which are generally caused by rupture of geological faults within an area of the earth. For the water supply network 110 shown in FIG. 1, a background event may be a failure that is caused by material fatigue and degradation of the component 112. The background event may or may not trigger another working event.

A triggered event is a working event that is caused by another working event. For the above-mentioned geologic system, the aftershocks may be considered as the triggered events since the aftershocks are caused by the main shocks. For the water supply network 110 shown in FIG. 1, a triggered event may be a failure that is caused by another failure. For example, a failure of a first component 112, particularly, a water leak on the first component 112, may lead to deteriorated bedding conditions around a second component 112, which may cause a failure of the second component 112. As another example, an on-site check process for a failure of the first component 112 may cause failures of the second component 112 in the vicinity of the check site. A triggered event may be caused by a background event or another triggered event.

For characterisation of the behaviours of the working events of the components 112, each working event is considered as a point in a stochastic point process in the present disclosure.

An Example Method

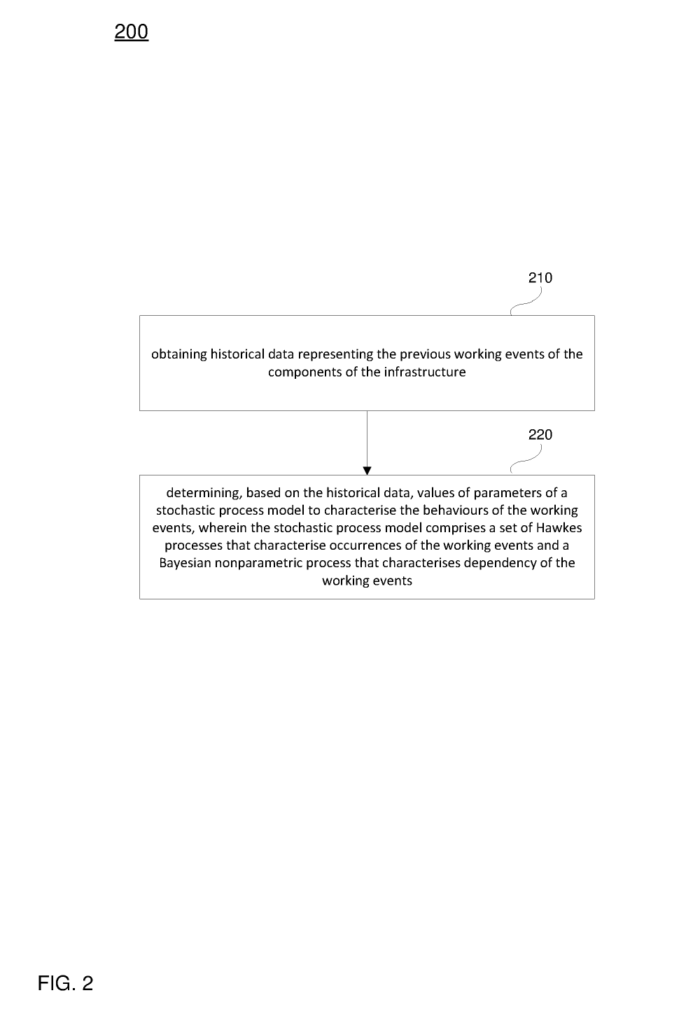

FIG. 2 illustrates an example method 200 for characterising behaviours of working events of the components 112 of the infrastructure 110.

In this example, the computing device 120 obtains 210 the historical data representing previous working events of the components 112 of the infrastructure 110. The previous working events in the present disclosure refers to the working events that occurred in the past.

A stochastic process model is used in the present disclosure to characterise the behaviours of the working events. The stochastic process model comprises a set of Hawkes processes and a Bayesian nonparametric process. The set of Hawkes processes are used to characterise occurrences of the working events and the Bayesian nonparametric process is used to characterise the dependence of the working events. According to the dependency of the working events, the working events are divided into clusters. Each of the clusters includes a background event. And each of the clusters may also include triggered events if the background event has triggered other events. The occurrence rate of the working events in each of the clusters is characterised by one of the set of the Hawkes processes.

Based on the historical data, the computing device 120 determines 220 values of parameters of the stochastic process model that is used to characterise the behaviours of the working events. In this example, the parameters of the stochastic process model include parameters of the set of Hawkes processes and variables of the Bayesian nonparametric process. Therefore, once the values of parameters of the stochastic process model are determined, the values of the parameters of the set of Hawkes processes and the values of the variables of the Bayesian nonparametric process are determined accordingly.

It should be noted that since the stochastic process model is a statistic model, the model does not only apply to the previous working events, but also to future working events.

In this example, the dependency of the working events serves as prior knowledge on the occurrences of the working events, which enhances the set of Hawkes processes in characterising the occurrences of the working events. As a result, the behaviours of the working events may be accurately characterised by the stochastic process model. Further, an accurate estimate of a quantity of future working events may be achieved based on one of the set of Hawkes processes.

A further example method

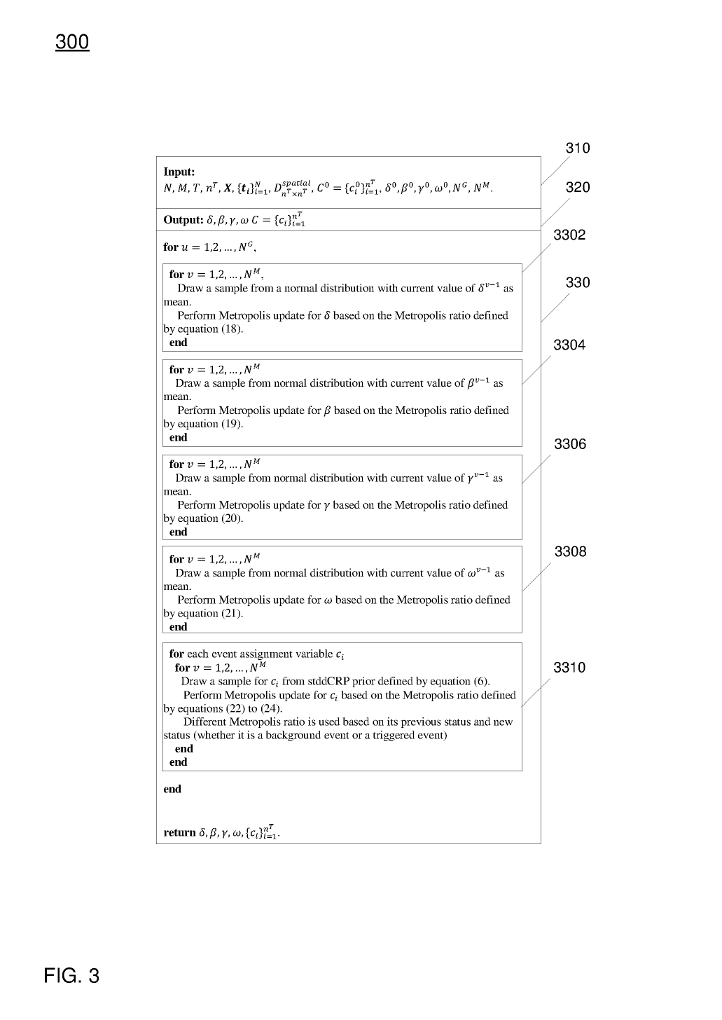

FIG. 3 illustrates a further example method 300 for characterising behaviours of working events of the components 112 of the infrastructure 110.

Similar to the method 200 described with reference to FIG. 2, the stochastic process model used in the method 300 includes two modules: a set of Hawkes processes to characterise occurrences of the working events and a Bayesian nonparametric process to characterise the dependency of the working events.

Since the behaviours of the working events exhibit spatiotemporal clustering feature, a spatiotemporal distance dependent Chinese restaurant process (stddCRP) is used in this example as the Bayesian nonparametric process to characterise the spatiotemporal dependence of the working events, wherein each of the variables of the stddCRP is associated with a previous working event and the value of the variable associated with the previous working event indicates the spatiotemporal dependency of the previous working event.

To determine the values of the parameters of the set of Hawkes processes and the values of the variables of stddCRP, an iterative learning process is adopted to alternately update the values of the parameters of the set of Hawkes processes and the values of the variables of the stddCRP from initial values of the parameters of the set of Hawkes processes and initial values of the variables of the stddCRP. This way, the resulting values of the parameters of the set of Hawkes processes result in an accurate working event estimate since the spatiotemporal dependency, particularly, types, of the working events are taken into account when determining the values of the parameters of the set of Hawkes processes.

It is worth noting that many state-of-the-art approaches, for example, the method described in Z. Li, Y. Wang, F. Chen, “Bayesian nonparametric method for infrastructure failure prediction”, WO 2014085849 A1. PCT/AU2013/001,395) can estimate the failure probability for a unit of time, e.g., a year, while from one of the set of Hawkes processes with the values of the parameters thereof determined according to this example, the number of the working events may be estimated for any specified future time interval.

### Hawkes Process

As described above, the occurrence rate of working events is characterised by a Hawkes process in this example, as shown in equation (1), which is referred to as the intensity function of the Hawkes process.

$$λ ( t ) = μ ( t ) + {\sum }_{t > {t}_{i}} g ( t - {t}_{i} ) , \qquad ( 1 )$$

where μ(t) represents background intensity that models background events and g(t) is triggering kernel that models triggered events. The two branches in equation (1) reflect different generation mechanisms for two different types of working events.

In the Hawkes process described in Alan G. Hawkes, “Point spectra of some self-exciting and mutually-exciting point processes”, Journal of the Royal Statistical Society, Series B (Methodological), 58:83-90, 1971, the background intensity is a constant, which means the background intensity does not vary over time. This setting may suit some scenarios, such as seismic analysis and epidemic analysis. However, the constant background intensity may not be applicable if the intensity of the working events of the components 112 change over time, for example, due to material fatigue or degradation of the components 112. Further, the background intensity may also vary with attributes of the components 112 of the infrastructures 110, for example, material type, size, and construction year. Therefore, in this example, the background intensity of the Hawkes process takes into account time and the attributes of a particular component 112, as shown in equation (2) below.

μ(t)=δt^{δ-1}e^{x}^{_{T}}^{β} (2)

where t represents time, x represents the attributes of a particular component 112 of the infrastructure 110. δ and β are parameters that need to be determined from the previous working events via the learning process. Note that x may be a vector including multiple attribute elements, for example, material type, size, and construction year. In the case of x being a vector including multiple attribute elements, β in equation (2) is a vector accordingly, which provides a weight for each of the attribute elements. T in the above equation (2) represents the transpose of x.

For the triggering kernel modelling the triggered events, the form of the triggering kernel described in Alan G. Hawkes, “Point spectra of some self-exciting and mutually-exciting point processes”, Journal of the Royal Statistical Society, Series B (Methodological), 58:83-90, 1971, is adopted in this example, as shown in equation (3):

g(t)=γω^{-ωt} (3)

where γ and ω are the parameters that need to be determined from the previous working events via the learning process.

The Hawkes process described in Alan G. Hawkes, “Point spectra of some self-exciting and mutually-exciting point processes”, Journal of the Royal Statistical Society, Series B (Methodological), 58:83-90, 1971, is a self and mutually-exciting Markov point process. However, the Hawkes process used in this example models any spatiotemporal excitations within the spatiotemporal cluster given by the stddCRP, and the number of clusters governed by the stddCRP may increase with the increase of the number of the working events.

Therefore, the intensity function for the set of Hawkes processes in this example can be defined as:

$$λ ( t ) = {λ}_{k} ( t ) = δ {t}^{δ - 1} {e}^{{x}^{T} β} + {\sum }_{t > {t}_{i} {t}_{i} ∈ {N}_{k}} γω {e}^{- ω ( t - {t}_{i} )} , k = 1 … {N}_{c} \qquad ( 4 )$$

where λₖ(t) represents the intensity function for a cluster k, tᵢ represents the time of the working event occurred before t in the cluster k, Nₖ represents the working events in the cluster k, N_{c} represents the number of clusters. Thus, the intensity for the cluster k is equal to its background intensity plus triggered intensity from the spatiotemporal excitations. As can be seen from equation (4), the intensity function for the set of Hawkes processes includes a set of intensity functions, each of which is for a cluster of the working events. Further, the values of the parameters of the set of the Hawkes processes, δ, β, γ, ω, are the same to each of the set of Hawkes processes.

According to local Janossy measure, the likelihood function for the set of Hawkes processes can be represented as below:

$$L = \frac{{\prod }_{i = 1}^{n} λ ( {t}_{i} )}{exp ( {\int }_{0}^{T} λ ( t ) dt )} \qquad ( 5 )$$

### Spatiotemporal Distance Dependent Chinese Restaurant Process (stddCRP)

As described above, the stddCRP is used in this example as the Bayesian nonparametric prior to characterise the spatiotemporal dependency, particularly, the spatiotemporal clustering feature, of the working events. It should be noted the types of a working events are usually unknown beforehand when the working event occurs according to the intensity function(s) of the Hawkes process defined by equation (1) or (4), but the stddCRP provides a proper prior, through which, based on the previous working events, the behaviours of the working events may be characterised and the number of clusters may be determined.

The spatiotemporal dependency or spatiotemporal clustering feature of the working events provides an important lead for determining the types of the working events because the background events generally spread over time without apparent clustering feature while the triggered events exhibit strong spatiotemporal clustering feature. The types of the working events may facilitate determination of the values of the parameters of the set of Hawkes processes shown in equation (4).

The stddCRP used in this example derives from a distance dependent Chinese Restaurant Process (ddCRP), as described in Blei, David M., and Peter I. Frazier. “Distance dependent Chinese restaurant processes”, The Journal of Machine Learning Research 12 (2011): 2461-2488, which is an extension of the Chinese Restaurant Process (CRP). The CRP is a generative clustering process that allows the number of clusters to be determined from the previous working events.

Take a restaurant with an infinite number of tables as an example, each table represents a cluster which is governed by a generating distribution. Each customer represents a working event. Customers enter the restaurant sequentially. The customers either sit at a table that has been occupied with a probability proportional to the number of the occupants, or sit at a new table with a probability proportional to a scaling parameter α. The sitting of all the customers provides a clustering pattern, and each customer is a draw from the generating distribution governing the table. The CRP inference gives a posterior distribution of the table assignments namely clustering assignments and the parameters for the tables' distributions.

Unlike CRP, which performs clustering via table assignments, the ddCRP indirectly determines the clustering pattern through customer assignments cᵢ, where i ∈ [1, N] is the customer index and N is the number of customers. The probability for a customer being assigned to another customer is proportional to the outcome of a decay function f which takes the distance between two customers as input. The probability for a customer being assigned to himself or herself is proportional to a scaling parameter α. The customers assigned together form a cluster. Formally, we can use cᵢ˜ddCRP(α, f, D) to indicates that the customer assignments follow the ddCRP where D represents the distance matrix for the customers.

For the stddCRP used in this example, each working event may be considered as a customer for the purpose of understanding this example. In this context, the customer assignments and the customer assignment variables cᵢ may be referred to as event assignments and event assignment variables cᵢ, respectively.

Each of the variables of the stddCRP is associated with a previous working event, the value of the variable associated with the previous working event indicates the dependency of the previous working event.

In this example, the spatialtemporal dependency of the previous working events includes spatial dependency and temporal dependency. The spatial dependency is determined by a difference between times of the occurrences of a first previous working event and a second previous working event, or a temporal distance. The spatial dependency is determined by a difference between locations of the occurrences of the first previous working event and the second previous working event, or a spatial distance.

If the temporal distance is less than a temporal threshold and the spatial distance is less than a spatial threshold, the second previous working event is dependent on the first previous working event, which means the second working event is a triggered event. Otherwise, the second previous working event is dependent on itself, which means the second previous working event is a background event.

The stddCRP takes into account both spatial distance and temporal distance for event assignment. This is achieved via a decay function defined on spatiotemporal distance. Specifically, the event assignments follow the stddCRP, cᵢ˜stddCRP(α, f, D^{spatial}, D^{temporal}). The event assignments indirectly determine the spatiotemporal cluster assignments zᵢ. The parameters of stddCRP, α, f, D^{spatial}, D^{temporal}, will be explained later.

For the stddCRP, the event assignments are drawn independently, conditioned on spatiotemporal distance measurements:

$$p ( {c}_{i} = j \vert α , f , {D}^{spatial} , {D}^{temporal} ) ∝ \{ \begin{matrix}f ( {d}_{ij}^{spatial} , {d}_{i}^{temporal} - {d}_{j}^{temporal} ) , & if i \neq j \\ α & if i = j\end{matrix} , \qquad ( 6 )$$

where dᵢⱼ^{spatial} denotes the spatial distance between two working events i, j and dᵢ^{temporal}−dⱼ^{temporal} or dᵢⱼ^{temporal} indicates the temporal distance between two working events i, j that occurred at time dᵢ^{temporal}, and dⱼ^{temporal}. f(dᵢⱼ^{spatial},dᵢⱼ^{temporal}) or f(d^{spatial},d^{temporal}) represents the decay function defined on spatiotemporal distance between the two working events i and j. D^{spatial} is the spatial matrix that represents the spatial distance between two working events, and D^{temporal} the temporal matrix represents the temporal distance between two working events. α is a pre-set scaling parameter of the stddCRP.

The decay function f(d^{spatial}, d^{temporal}) may take different forms. A spatiotemporal window decay function is provided below for description purposes:

$$f ( {d}^{spatial} , {d}^{temporal} ) = \{ \begin{matrix}1 , & {d}^{spatial} \leq {d}_{threshold}^{spatial} 0 \leq {d}^{temporal} \leq {d}_{threshold}^{temporal} \\ 0 , & otherwise\end{matrix} . \qquad ( 7 )$$

It can be seen from the above equation (7), a working event i depends on another working event j if the spatial distance d^{spatial} between i and j is less than a spatial threshold d_{threshold}^{spatial}, and the working event i occurs within a temporal threshold d_{threshold}^{temporal} from the time of the working event j, which means the working event i occurs in the time interval [dⱼ^{temporal},dⱼ^{temporal}+d_{threshold}^{temporal}].

It is worth noting that, when d_{threshold}^{spatial}=0, the stddCRP reduces to model temporal clustering clustering feature only (the Hawkes process degrades to the self-exciting Hawkes process). In this case, the behaviours of the working events of the components 112 are characterised by their temporal dependency without spatial dependency. Further, if both d_{threshold}^{spatial} and d_{threshold}^{temporal} are equal to zero, then stddCRP may be further reduced to a nonhomogeneous Poisson process without any spatiotemporal clustering information.

### The Inference Algorithm

FIG. 3 illustrates a method 300 for characterising the behaviours of working events of the components 112 of the infrastructure 110.

To determine the values of the parameters of the stochastic process model including the set of Hawkes processes and the stddCRP, a posterior inference using Markov chain Monte Carlo (MCMC) is performed in this example. There is no conjugate prior for the likelihood function of the set of Hawkes processes. The Metropolis-within-Gibbs sampling for inferring model parameters is applied in this example. The inference steps are shown in FIG. 3, as described below.

The input of the method 300 is shown in the “Input” section 310 of FIG. 3. Particularly:
N: the number of the components 112 of the infrastructure 110;
M: the number of attributes of the components 112;
T: the event observation time span. The historical working events are observed in a time span [0, T], e.g., from year 2001 to year 2010. The start of the time span is considered as 0 for derivation convenience;
n^{T}: the total number of working events of the N components 112 occurred in time span [0, T];
attribute matrix X={xᵢⱼ}, where i ∈ [1, N], j ∈ [1, M]: the values of the attributes of the components 112. Each row of the attribute matrix represents the values of the attributes of a particular component 112, for example, (80, 100, 120, 1, 1), representing the values of attributes of the component 112, for example, age, diameter size, length, whether it is a cast iron concrete lined (CICL) component and whether it has coating. The first three attributes are represented by real numbers while the last two attributes are represented by Boolean values with 1 indicating the attribute is true and 0 otherwise. The age of the component 112 here means the age since the observation starts;
working event record {tᵢ}ᵢ₌₁^{N}: the times of the previous working events of the components 112. Each vector tᵢ contains nᵢ elements, indicating the times of nᵢ working events for the i-th component 112. For example, a 10-year observation can be indexed by 36500 days, and a particular component's 112 working event record may be t₁₀={10, 400, 520, 2000}, which means the working events of the component No. 10 occurred on days 10, 400, 520 and 2000;
spatial distance matrix Dₙ_{^{T}}_{×n}_{^{T}}^{spatial}: the spatial distance of each pair of the working events;
initial values of variables C⁰={cᵢ⁰}ᵢ₌₁ⁿ^{^{T}}: in this example, the variables of the stddCRP is represented by C={cᵢ}ᵢ₌₁ⁿ^{^{T}}. The initial value of each event assignment variable cᵢ⁰ for inference may be set to itself, i.e., cᵢ=i, which means the working event No. i depends on itself initially. That is, all the working events are the background events initially;
δ⁰, β⁰, γ⁰, ω⁰: the initial values of the parameters δ, β, γ, ω of the set of Hawkes processes;
N^{G}: the number of iterations for Gibbs sampling;
N^{M}: the number of iterations for Metropolis sampling.

The output of the method 300 is shown in the “Output” section 320 of FIG. 3. Particularly:
δ, β, γ, ω: the values of the parameters of the set of Hawkes processes;
C={cᵢ}ᵢ₌₁ⁿ^{^{T}}: the values of the variables of the stddCRP used to characterise the dependency of the working events.
It can be seen from the “Input” and “Output” sections 310, 320 that the learning process shown in FIG. 3 is to determine the values of the parameters of the set of Hawkes processes and the values of the variables of the stddCRP given the working event observation of the components 112 and the attributes of the components 112. That is, the posterior of the parameters δ, β, γ, ω, C in the following equation (8) need to be determined:

p(δ,β,γ,ω,C|T,X)∝p(δ,β,γ,ω,C)p(T,X|δ,β,γ,ω,C). (8)

Without knowing the variables cᵢ of the stddCRP C, the likelihood function defined by equation (5) can be represented via a set of intermediate variables:

$$\begin{matrix}p ( T , X \vert δ , β , γ , ω ) = {\prod }_{i = 1}^{{n}_{T}} λ ( {t}_{i} ) exp ( - Λ ( T ) ) , & ( 9 ) \\ Λ ( T ) = {\int }_{0}^{T} λ ( t ) dt = M ( T ) + {\sum }_{t > {t}_{i} {t}_{i} ∈ {N}_{k}} γ B ( T , {t}_{i} ) & ( 10 ) \\ M ( T ) = {\int }_{0}^{T} δ {t}^{δ - 1} {e}^{{x}^{T} β} dt & ( 11 ) \\ B ( T , {t}_{i} ) = {\int }_{0}^{T} ω {e}^{- ω ( t - {t}_{i} )} dt . & ( 12 )\end{matrix}$$

Once the stddCRP C is known, the intensity function defined by equation (4) can be explicitly split into the background intensity and the triggered intensity:

λ_{B}(t)=δt^{δ-1}e^{x}^{^{T}}^{β}, (13)

λ_{O}(t)=γωe^{-w(t-t}^{^{pa}}⁾. (14)

where t^{pa} denotes the time of the triggering event of the triggered event. It should be noted that the triggering event may be a background event or a triggered event.

Accordingly, given the stddCRP C, the likelihood function can be further written as:

$$\begin{matrix}p ( T , X \vert δ , β , γ , ω , C ) = p ( {T}^{B} , {X}^{B} \vert δ , β , γ , ω , C ) p ( {T}^{O} , {X}^{O} \vert δ , β , γ , ω , C ) , & ( 15 ) \\ p ( {T}^{B} , {X}^{B} \vert δ , β , γ , ω , C ) = ( {\prod }_{{t}_{i} ∈ B} δ {{t}_{i}}^{δ - 1} {e}^{{x}^{T} β} ) exp ( - M ( T ) ) & ( 16 ) \\ p ( {T}^{O} , {X}^{O} \vert δ , β , γ , ω , C ) = ( {\prod }_{{t}_{i} ∈ O} γω {e}^{- ω ( {t}_{i} - {t}^{pa} )} ) exp ( - {\sum }_{{t}_{j} ∈ {T}^{P}} γ B ( T , {t}_{j} ) ) & ( 17 )\end{matrix}$$

where B and O indicate the set of background events and the set of triggered events, respectively; T^{B} and T^{O} represent the times of the background events and the times of the triggered events, respectively; T^{P} represents the times of background events that have triggered other events.

In order to determine the model parameters, the Metropolis-within-Gibbs sampling algorithm is applied to the stochastic process model, as shown in the section 330 of FIG. 3.

The algorithm alternately updates the values of the parameters of the stochastic process model, particularly, the values of the parameters of the set of Hawkes processes and the values of the variables of the stddCRP, as shown in steps 3302, 3304, 3306, 3308 and 3310, in which the Metropolis-Hasting sampling algorithm is used.

The normal distribution is used as the proposal distribution for parameters δ, β, γ and ω. And independent exponential priors are used for these parameters as initial values for inference, e.g., (δ⁰,β⁰,γ⁰, ω⁰)=(e^{0.01}, e^{0.01}, e^{0.01}, e^{0.01}) The acceptance ratios for the Metropolis-Hasting update used in steps 3302, 3304, 3306, 3308 are given by the following equations:

$$\begin{matrix} {a}_{δ} = \frac{p ( \tilde{δ} , β , γ , ω )}{p ( δ , β , γ , ω )} {\prod }_{{t}_{i} ∈ B} ( \frac{\tilde{δ} {t}_{i }^{\tilde{δ} - 1}}{δ {t}_{i}^{δ}} ) exp ( M ( T ) - \tilde{M} ( T ) ) , & ( 18 ) \\ {a}_{β} = \frac{p ( δ , \tilde{β} , γ , ω )}{p ( δ , β , γ , ω )} {\prod }_{{t}_{i} ∈ B} ( {e}^{{x}^{T} ( \tilde{β} - β )} ) exp ( M ( T ) - \tilde{M} ( T ) ) , & ( 19 ) \\ {a}_{γ} = \frac{p ( δ , β , \tilde{γ} , ω )}{p ( δ , β , γ , ω )} {\prod }_{{t}_{i} ∈ O} ( \frac{\tilde{γ}}{γ} ) exp ( {\sum }_{{t}_{j} ∈ {T}^{P}} ( γ - \tilde{γ} ) B ( T , {t}_{j} ) ) , & ( 20 ) \\ {a}_{ω} = \frac{p ( δ , β , γ , \tilde{ω} )}{p ( δ , β , γ , ω )} {\prod }_{{t}_{i} ∈ O} ( \frac{\tilde{ω} {e}^{- \tilde{ω} ( {t}_{i} - {t}^{pa} )}}{ω {e}^{- ω ( {t}_{i} - {t}^{pa} )}} ) exp ( {\sum }_{{t}_{j} ∈ {T}^{P}} γ ( B ( T , {t}_{j} ) - \tilde{B} ( T , {t}_{j} ) ) ) , & ( 21 )\end{matrix}$$

where variables with ˜ mark represent the variables with proposed new values.

In step 3302, the parameter δ of the set of Hawkes processes is updated based on the acceptance ratio defined by equation (18). It should be noted that equation (18) applies to the set of the background events B, which can be determined based on dependency of the previous working events indicated by the stddCRP. Particularly, if a previous working event i is dependent on itself, i.e., cᵢ=i, the previous working event is determined to be a background event. The set of the background events B consists of the background events in the previous working events.

In step 3304, the parameter β of the set of Hawkes processes is updated based on the acceptance ratio defined by equation (19). It should be noted that equation (19) applies to the set of the background events B. As can be seen from equation (19), the updating of the parameter β may also be based on the values of attributes of the components 112, which may comprise age, diameter, length, material and coating of the components 112.

In step 3306, the parameter γ of the set of Hawkes processes is updated based on the acceptance ratio defined by equation (20). It should be noted that equation (20) applies to the set of the triggered events O, which can be determined based on dependency of the previous working events indicated by the stddCRP. Particularly, if a previous working event i is dependent on another event j, i.e., cᵢ=j(i≠j), the previous working event i is determined to be a triggered event. The set of the triggered events O consists of the triggered events in the previous working events.

In step 3308, the parameter ω of the set of Hawkes processes is updated based on the acceptance ratio defined by equation (21). It should be noted that equation (21) applies to the set of the triggered events O.

Further, Metropolis-Hasting updates are performed to update the values of event assignment variables cᵢ of the stddCRP, as shown in step 3310. As described above, each of the event assignment variables cᵢ is associated with a previous working event and the value of the variable associated with the previous working event indicates the dependency of the previous working event.

The conditional prior defined by equation (6) is used as the proposal distribution in this example. Then the conditional prior and the proposal distribution will cancel each other, and only the ratio of likelihood function is left as the Hasting acceptance ratio. There are different situations in updating cᵢ: (1) updating from a background event to a triggered event, (2) updating from a triggered event to a background event, (3) change the parent event. The updating of the values of the event assignment variables cᵢ with respect to these situations is given by the following equations (22) to (24):

$$\begin{matrix}{a}_{{c}_{i}}^{B \to O} = \frac{p ( \tilde{{T}^{B}} , \tilde{{X}^{B}} \vert δ , β , γ , ω , C ) p ( \tilde{{T}^{O}} , \tilde{{X}^{O}} \vert δ , β , γ , ω , C )}{p ( {T}^{B} , {X}^{B} \vert δ , β , γ , ω , C ) p ( {T}^{O} , {X}^{O} \vert δ , β , γ , ω , C )} = \frac{γω {e}^{- ω ( {t}_{i} - {t}^{pa} )}}{δ {t}_{i}^{δ - 1} {e}^{{x}_{i}^{T} β}} , & ( 22 ) \\ {a}_{{c}_{i}}^{O \to B} = \frac{p ( \tilde{{T}^{B}} , \tilde{{X}^{B}} \vert δ , β , γ , ω , C ) p ( \tilde{{T}^{O}} , \tilde{{X}^{O}} \vert δ , β , γ , ω , C )}{p ( {T}^{B} , {X}^{B} \vert δ , β , γ , ω , C ) p ( {T}^{O} , {X}^{O} \vert δ , β , γ , ω , C )} = \frac{δ {t}_{i}^{δ - 1} {e}^{{x}_{i}^{T} β}}{γω {e}^{- ω ( {t}_{i} - {t}^{pa} )}} , & ( 23 ) \\ {a}_{{C}_{i}}^{O \to \tilde{O}} = \frac{p ( \tilde{{T}^{O}} , \tilde{{X}^{O}} \vert δ , β , γ , ω , C )}{p ( {T}^{O} , {X}^{O} \vert δ , β , γ , ω , C )} = \frac{{e}^{- ω ( {t}_{i} - {t}^{\tilde{pa}} )}}{{e}^{- ω ( {t}_{i} - {t}^{pa} )}} , & ( 24 )\end{matrix}$$

As can be seen from the above equations, the updating of the values of the event assignment variables cᵢ may be based on the parameters δ, β, γ, ω of the set of Hawkes processes. Further, equations (22) and (23) indicate that the updating of the values of the event assignment variables cᵢ may be based on the values of attributes of the components 112.

Upon completion of Metropolis-within-Gibbs sampling shown in the section 330, the values of the parameters δ, β, γ, ω of the set of Hawkes processes and the values of the event assignment variables {cᵢ}ᵢ₌₁ⁿ^{^{T}} of the stddCRP may be determined. The types of the working events can also be obtained via the event assignment variables cᵢ as described above.

### Estimation of Future Working Events

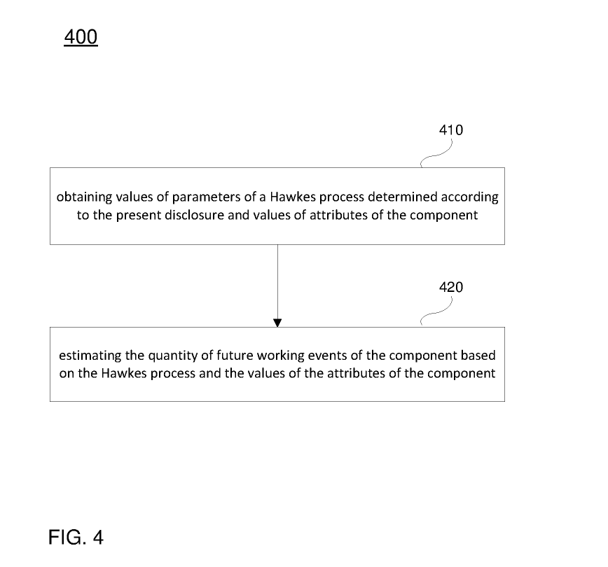

FIG. 4 illustrates an example method 400 for estimating a quantity of future working events of a component 112 of the infrastructure 110.

In this example, the values of the parameters δ, β, γ, ω of the set of Hawkes processes and the values of the variables C={cᵢ}ᵢ₌₁ⁿ^{^{T}} of the stddCRP are determined from the above inference process. As described above, the values of the parameters of the set of the Hawkes processes, δ, β, γ, ω, are the same to each of the set of Hawkes processes. Therefore, the computing device 120 may use the intensity function for one of the set of Hawkes processes defined by equation (4) to estimate a quantity of future working events of the component 112 of the infrastructure 110.

In this example, the computing device 120 obtains 410 the values of parameters of the Hawkes process determined according to the method described above and values of attributes of the component 112.

The computing device 120 estimates 420 the quantity of future working events of the component 112 based on the Hawkes process and the values of the attributes of the component.

Particularly, the computing device 120 may determine an expression for the Hawkes process, as shown in equation (4), based on the values of the parameters of stochastic process and integrate the expression for the Hawkes process over a period of time.

Although the Hawkes process defined by equation (4) includes the background intensity and the triggered intensity, the computing device 120 may only use the background intensity, defined by equation (13), to estimate the quantity of the working events in a future period of time because the triggering effect may only exists in a near future period of time and thus the previous working events will not be able to have the triggering effect for a far future period of time. Further, in some cases, for example, a water supply network, the majority of the working events (for example, failures) are background events. Therefore, the estimate that only results from the background intensity may provide a sufficient accuracy in estimating the future working events.

For example, to estimate the number of working events of a component 112 having the attributes of (80, 100, 120, 1, 1) for the next 10 years since 2011, x=(80, 100, 120, 1, 1) and the obtained parameters δ and β are fed into the background intensity defined by equation (13). As a result, the computing device 120 determines part of the expression for the Hawkes process.

Then the number of working events of the component 112 for the next 10 years can be estimated as the integral of the part of the expression, i.e., the background intensity, over a period of time t=[0,3650].

It should be noted that since the background intensity is the same to each of the set of the Hawkes processes, as shown in equation (4), and the triggered intensity does not affect the accuracy of the estimation. Therefore, any one of the set of the Hawkes processes may be used to estimate the quantity of future working events of the component 112.

Performance Analysis

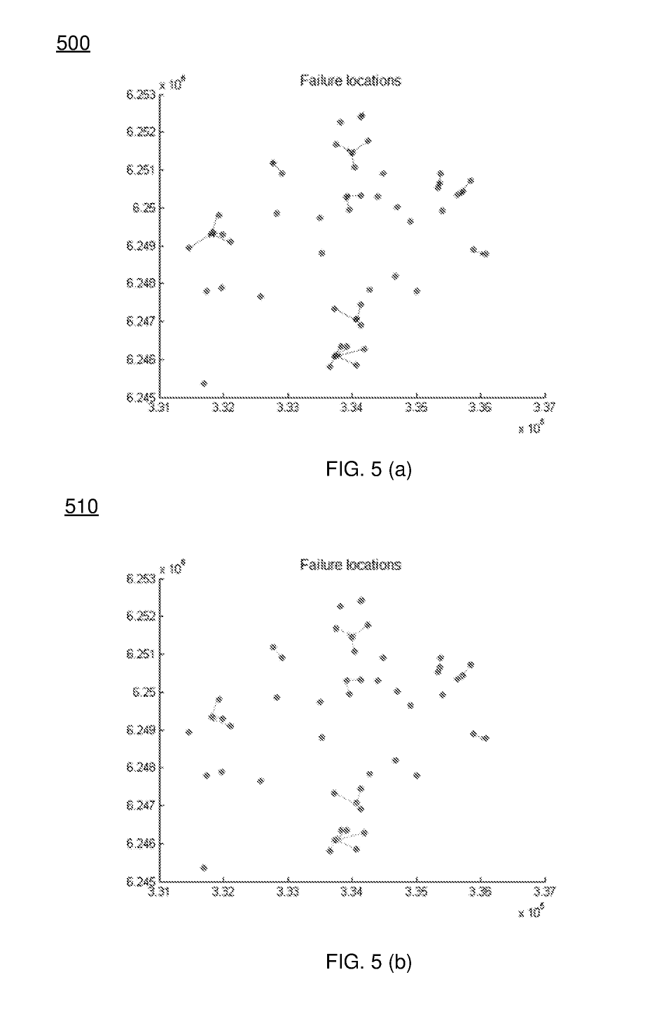

FIGS. 5(a) and 5(b) illustrate a performance analysis of the method 300 described above.

50 working events are shown in FIG. 5(a). A dot in FIG. 5(a) represents a working event in a spatial space. The arrows indicate the ground truth of the dependency 500 of the working events, which represents the triggering relationships. Particularly, an arrow points from a triggered event to its triggering event. The temporal information of the working events is ignored in FIG. 5(a).

The dependency 510 of the working events determined according to the method 300 as describe above is shown in FIG. 5(b). As described above, the dependency 510 is numerically represented by the values of the variables of the stddCRP determined according to the method 300. In this example, the dependency 510 is graphically represented by the arrows. As can be seem, 19 out of 22 triggering relationships are found by the method 300.

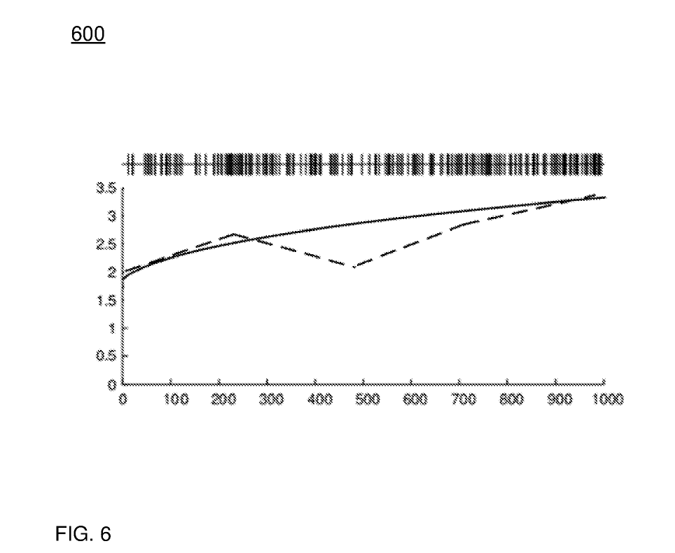

FIG. 6 illustrates a further performance analysis 600 of the method 300 described above.

In FIG. 6, 500 working events for 10 components are generated to demonstrate the determining of the background intensity of the Hawkes process. The working events are generated for a time period of 1000 days.

FIG. 6 illustrates the result for one of the components. The values of the attributes of this component are (80,100,120,1,1). 100 working events for this component are shown as vertical bars in FIG. 6. The solid curve represents the ground truth of the background intensity of the Hawkes process used to generate the working events. The dash curve represents the background intensity determined according to the method 300 for the same period of time. It can be seen from FIG. 6 that the background intensity determined according to the method 300 fits the ground truth of the background intensity well.

Hardware System

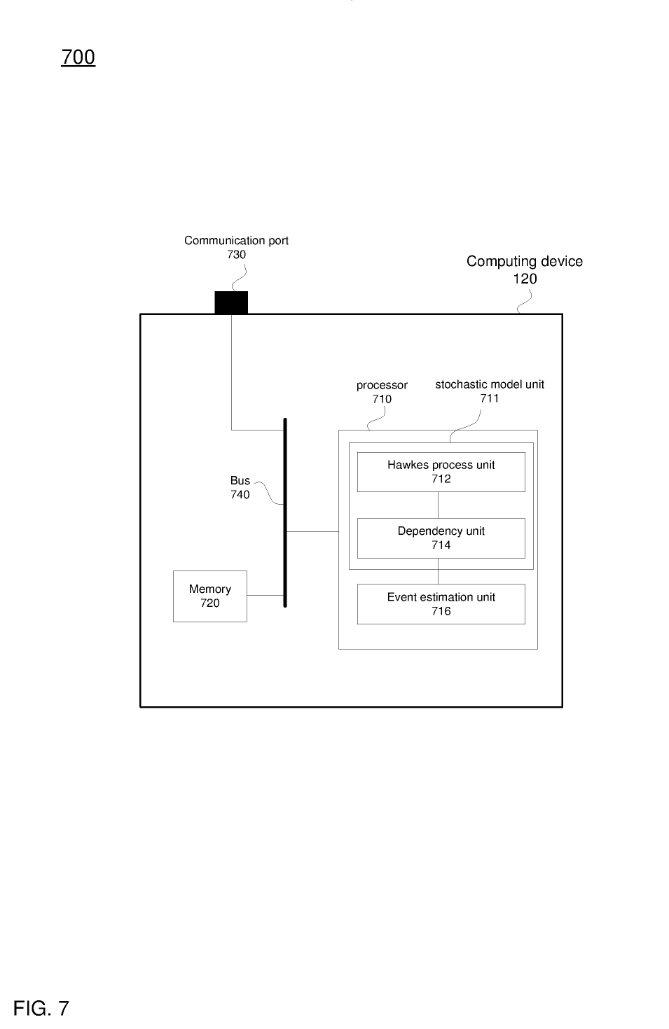

FIG. 7 illustrates an example schematic diagram 700 of the computing device 120 used to implement the example methods described above.

The computing device 120 shown in FIG. 7 includes a processor 710, a memory 720, a communication port 730 and a bus 740. The processor 710, the memory 720, the communication port 730 are connected through the bus 740 to communicate with each other.

The processor 710 performs instructions stored in the memory 720 to implement the example methods described above with reference to the computing device 120 according to the present disclosure.

The processor 710 further includes, a stochastic model unit 711 and an event estimation unit 716. The stochastic model unit 711 includes a Hawkes process unit 712 and a dependency unit 714. The separate units 711 to 716 of the processor 710 are organised in a way shown in FIG. 7 for illustration and description purposes only, which may be arranged in a different way. Specifically, one or more units in the processor 710 may be part of another unit. For example, the dependency unit 714 may be integrated with the Hawkes process unit 712. In another example, one or more units, particularly, the event estimation unit 716, in the processor 710 shown in FIG. 7 may be separate from the processor 710 without departing from the scope of the present disclosure.

Further, depending on the intended functions of the computing device 120, one or more units 711 to 716 may not be necessary for the computing device 120 to perform the functions. For example, the event estimation unit 716 may not be necessary for the computing device 120 to determine the values of the parameters of the set of Hawkes processes and the values of the variables of the stddCRP.

The communication port 730 of the computing device 120 obtains the historical data representing the previous working events of the components 112 of the infrastructure 110.

The stochastic model unit 711 of the processor 710 determines, based on the historical data, values of parameters of a stochastic process model to characterise the behaviours of the working events. As described above, the stochastic process model comprises a set of Hawkes processes that characterise occurrences of the working events and a Bayesian nonparametric process that characterises dependency of the working events.

As described above, a spatiotemporal distance dependent Chinese restaurant process (stddCRP) is used as the Bayesian nonparametric process. Therefore, the Hawkes process unit 712 of the stochastic model unit 711 uses the historical data to determine values of the parameters of the set of Hawkes processes, as described above with reference to the steps 3302 to 3308 in FIG. 3. Further, the dependency unit 714 of the stochastic model unit 711 determines, based on the historical data, values of variables of the stddCRP, as described above with reference to the step 3310 in FIG. 3.

On the other hand, as described with reference to FIG. 4, once the values of the parameters δ, β, γ, ω of the set of Hawkes processes and the values of the variables C={cᵢ}ᵢ₌₁ⁿ^{^{T}} of the stddCRP are determined, the intensity function of one of the set of Hawkes processes defined by equation (4) can be used to estimate the quantity of future working events of a component 112 of the infrastructure 110.

Particularly, the communication port 730 of the processor 710 obtains the values of the parameters of the Hawkes process and values of attributes of the component 112. The values of the parameters of the Hawkes process may be determined according to the methods described above or from another computing device implementing the methods described above.

The event estimation unit 716 of the processor estimates the quantity of future working events of the component 112 based on the Hawkes process and the values of the attributes of the component.

Particularly, the event estimation unit 716 may determine an expression for the Hawkes process, i.e., the intensity function as shown in equation (4), based on the values of the parameters and integrate the expression for the Hawkes process over a period of time.

Further, as described above, the event estimation unit 716 may only integrate part of the expression, i.e., the background intensity of the intensity function, to estimate the quantity of the working events of the component 112.

It should be understood that the example methods of the present disclosure might be implemented using a variety of technologies. For example, the methods described herein may be implemented by a series of computer executable instructions residing on a suitable computer readable medium. Suitable computer readable media may include volatile (e.g. RAM) and/or non-volatile (e.g. ROM, disk) memory, carrier waves and transmission media. Exemplary carrier waves may take the form of electrical, electromagnetic or optical signals conveying digital data steams along a local network or a publically accessible network such as internet.

It should also be understood that, unless specifically stated otherwise as apparent from the following discussion, it is appreciated that throughout the description, discussions utilizing terms such as “determining”, “obtaining”, or “updating” or “estimating” or “modelling” or the like, refer to the action and processes of a computer system, or similar electronic computing device, that processes and transforms data represented as physical (electronic) quantities within the computer system's registers and memories into other data similarly represented as physical quantities within the computer system memories or registers or other such information storage, transmission or display devices.

1. A computer-implemented method for characterising behaviours of working events of components of an infrastructure, the working events comprising previous working events, the method comprising:
obtaining historical data representing the previous working events of the components of the infrastructure; and
determining, based on the historical data, values of parameters of a stochastic process model to characterise the behaviours of the working events, wherein the stochastic process model comprises a set of Hawkes processes that characterise occurrences of the working events and a Bayesian nonparametric process that characterises dependency of the working events.

2. The computer-implemented method according to claim 1, wherein determining the values of the parameters of the stochastic process model comprises determining values of parameters of the set of Hawkes processes and values of variables of the Bayesian nonparametric process.

3. A computer-implemented method according to claim 2, wherein the Bayesian nonparametric process comprises a spatiotemporal distance dependent Chinese restaurant process (stddCRP).

4. A computer-implemented method according to claim 3, wherein determining the values of the variables of the Bayesian nonparametric process comprises determining values of variables of the stddCRP, wherein each of the variables of the stddCRP is associated with a previous working event of the previous working events and the value of the variable associated with the previous working event indicates the dependency of the previous working event.

5. A computer-implemented method according to claim 4, wherein determining the values of variables of the stddCRP comprises updating the values of the variables of the stddCRP based on the values of the parameters of the set of Hawkes processes.

6. A computer-implemented method according to claim 5, wherein updating the values of the variables of the stddCRP comprises updating the values of the variables of the stddCRP based on values of attributes of the components.

7. A computer-implemented method according to claim 4, wherein determining the values of the parameters of the set of Hawkes processes comprises updating the values of the parameters of the set of Hawkes processes based on the dependency of the previous working events.

8. A computer-implemented method according to claim 7, wherein updating the values of the parameters of the set of Hawkes processes comprises updating the values of the parameters of the set of Hawkes processes based on the values of the attributes of the components.

9. A computer-implemented method according to claim 6, wherein the attributes of the components comprise age, diameter, length, material and coating of the components.

10. A computer-implemented method according to claim 7, wherein updating the values of the parameters of the set of Hawkes processes further comprises:
determining types of the previous working events based on the dependency of the previous working events; and
updating the values of the parameters of the set of Hawkes processes based on the types of the previous working events.

11. A computer-implemented method according to claims 10, wherein determining the types of the previous working events comprises determining a first portion of the previous working events to be background events if the values of variables of the stddCRP associated with the first portion of the previous working events indicate that each working event of the first portion of the previous working events is dependent on itself.

12. A computer-implemented method according to claim 10, wherein determining the types of the previous working events comprises determining a second portion of the previous working events to be triggered events if the values of variables of the stddCRP associated with the second portion of the previous working events indicate that each working event of the second portion of the previous working events is dependent on another previous working event.

13. A computer-implemented method according to claim 11, wherein updating the values of the parameters of the set of Hawkes processes comprises updating the values of one or more of the parameters of the set of Hawkes processes based on the first portion of the previous working events that are determined to be background events.

14. A computer-implemented method according to claim 12, wherein updating the values of the parameters of the set of Hawkes processes comprises updating the values of one or more of the parameters of the set of Hawkes processes based on the second portion of the previous working events that are determined to be triggered events.

15. A computer-implemented method according to claim 1, wherein the dependency of the working events comprises temporal dependency and spatial dependency.

16. A computer-implemented method for estimating a quantity of future working events of a component of an infrastructure, comprising:
obtaining values of parameters of a Hawkes process determined according to claim 2 and values of attributes of the component; and
estimating the quantity of future working events of the component based on the Hawkes process and the values of the attributes of the component.

17. A computer-implemented method according to claim 1, wherein the working events comprise failures of the components of the infrastructure.

18. A computer software program, including machine-readable instructions, when executed by a processor, causes the processor to perform the method of claim 1.

19. A computer software program, including machine-readable instructions, when executed by a processor, causes the processor to perform the method of claim 16.

20. A computer system for characterising behaviours of working events of components of an infrastructure, the working events comprising previous working events, the computer system comprising:
a communication port to obtain historical data representing the previous working events of the components of the infrastructure; and
a processor, comprising:
a Hawkes process unit to determine, based on the historical data, values of parameters of a set of Hawkes processes, wherein the set of Hawkes processes characterise occurrences of the working events; and
a dependency unit to determine, based on the historical data, values of variables of a Bayesian nonparametric process, wherein the Bayesian nonparametric process characterises dependency of the working events.

21. A computer system for estimating a quantity of future working events of a component of an infrastructure, comprising:
a communication port to obtain values of parameters of a Hawkes process determined according to claim 2, and values of attributes of the component; and
a processor, comprising
an event estimation unit to estimate the quantity of future working events of the component based on the Hawkes process and the values of the attributes of the component.
